(19) United States
(12) Patent Application Publication
(10) Pub. No.: US 2009/0087757 A1
(43) Pub. Date: Apr. 2, 2009

(54) METHOD FOR FEATURE PREDICTION, METHOD FOR MANUFACTURING PHOTOMASK, METHOD FOR MANUFACTURING ELECTRONIC COMPONENT, AND PROGRAM FOR FEATURE PREDICTION

(75) Inventor: Seiji ONOUE, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/238,795

(22) Filed: Sep. 26, 2008

(30) Foreign Application Priority Data
Sep. 28, 2007 (JP) 2007-256150

(51) Int. Cl. G03F 1/00; G06F 17/50; G03F 7/20

(52) U.S. Cl. 430/5; 716/5; 430/311

(57) ABSTRACT

A method for feature prediction, determining an incident angle at an incident amount prediction point on basis of a pattern data, determining an incident amount at the incident amount prediction point on basis of the incident angle and a process condition data, determining an incident amount distribution on basis of the incident amount at a plurality of the incident amount prediction points, selecting a feature prediction point on basis of the incident amount distribution and a predetermined threshold or a manufacturing history data, and performing prediction of a feature at the selected feature prediction point.

### CROSS-REFERENCE TO RELATED APPLICATIONS

This application is based upon and claims the benefit of priority from the prior Japanese Patent Application No. 2007-256150, filed on Sep. 28, 2007; the entire contents of which are incorporated herein by reference.

### BACKGROUND OF THE INVENTION

1. Field of the Invention

This invention relates to a method for feature prediction, a method for manufacturing a photomask, a method for manufacturing an electronic component, and a program for feature prediction.

2. Background Art

In the processes of film formation and etching for semiconductor devices, film formation and etching with very high accuracy are performed by plasma processing.

However, patterns in recent semiconductor devices have become remarkably finer. With the shrinkage of the design rule, it is more difficult to transfer a design pattern onto a wafer just as its desired features and dimensions.

In the steps of photolithography and etching, the dimensional accuracy of the feature to be formed is greatly affected by its layout environment of the other features placed therearound. Hence, a technique of process proximity correction processing is proposed, which uses the values of the dimension conversion difference determined stepwise in accordance with the distance between the opposed edges of opening features (see JP-A-2004-363390 (Kokai)).

However, in the technique disclosed in IP-A-2004-363390 (Kokai), the accuracy of feature prediction can be increased for linear features, but there is room for improvement in increasing the accuracy of feature prediction for nonlinear features (e.g., discontinuous and/or circular features) because of the effect of pattern features.

Furthermore, a technique for predicting the feature of a pattern formed by plasma processing is proposed (see JP-A-2006-074046 (Kokai)).

However, the technique disclosed in JP-A-2006-074046 (Kokai) performs feature prediction throughout the wafer. Hence, recent semiconductor devices with large size and high integration require time-consuming calculation because of enormous amounts of analysis data, and calculation may be performed for unnecessary portions of the wafer. Thus, there is room for improvement in increasing the analysis efficiency.

### SUMMARY OF THE INVENTION

According to an aspect of the invention, there is provided a method for feature prediction, determining an incident angle at an incident amount prediction point on basis of a pattern data, determining an incident amount at the incident amount prediction point on basis of the incident angle and a process condition data, determining an incident amount distribution on basis of the incident amount at a plurality of the incident amount prediction points, selecting a feature prediction point on basis of the incident amount distribution and a predetermined threshold or a manufacturing history data, and performing prediction of a feature at the selected feature prediction point.

According to another aspect of the invention, there is provided a method for feature prediction, determining an incident angle at an incident amount prediction point on basis of a pattern data, determining an incident amount at the incident amount prediction point on basis of the incident angle and a process condition data, determining an incident amount distribution on basis of the incident amount at a plurality of the incident amount prediction points, displaying the incident amount distribution, allowing an operator to select a feature prediction point on basis of the display, and performing prediction of a feature at the selected feature prediction point.

According to another aspect of the invention, there is provided a method for manufacturing a photomask, performing process proximity correction on a design pattern data on basis of a feature predicted by the method for feature prediction, determining an incident angle at an incident amount prediction point on basis of a pattern data, determining an incident amount at the incident amount prediction point on basis of the incident angle and a process condition data, determining an incident amount distribution on basis of the incident amount at a plurality of the incident amount prediction points, selecting a feature prediction point on basis of the incident amount distribution and a predetermined threshold or a manufacturing history data, and performing prediction of a feature at the selected feature prediction point, and creating an exposure pattern data.

According to another aspect of the invention, there is provided a method for manufacturing an electronic component, producing a photomask by the method for manufacturing a photomask, performing process proximity correction on a design pattern data on basis of a feature predicted by the method for feature prediction, determining an incident angle at an incident amount prediction point on basis of a pattern data, determining an incident amount at the incident amount prediction point on basis of the incident angle and a process condition data, determining an incident amount distribution on basis of the incident amount at a plurality of the incident amount prediction points, selecting a feature prediction point on basis of the incident amount distribution and a predetermined threshold or a manufacturing history data, and performing prediction of a feature at the selected feature prediction point, and creating an exposure pattern data, and performing exposure using the photomask.

According to another aspect of the invention, there is provided a method for manufacturing an electronic component, verifying a pattern data on basis of a feature predicted by the method for feature prediction, determining an incident angle at an incident amount prediction point on basis of a pattern data, determining an incident amount at the incident amount prediction point on basis of the incident angle and a process condition data, determining an incident amount distribution on basis of the incident amount at a plurality of the incident amount prediction points, selecting a feature prediction point on basis of the incident amount distribution and a predetermined threshold or a manufacturing history data, and performing prediction of a feature at the selected feature prediction point.

According to another aspect of the invention, there is provided a program for feature prediction causing a computer to: calculate an incident angle at an incident amount prediction point on basis of a pattern data; calculate an incident amount at the incident amount prediction point on basis of the incident angle and a process condition data; calculate an incident amount distribution on basis of the incident amount at a plurality of the incident amount prediction points; select a feature prediction point on basis of the incident amount distribution and a predetermined threshold or a manufacturing history data and perform prediction of a feature at the selected feature prediction point.

According to another aspect of the invention, there is provided a program for feature prediction causing a computer to: calculate an incident angle at an incident amount prediction point on basis of a pattern data; calculate an incident amount at the incident amount prediction point on basis of the incident angle and a process condition data; calculate an incident amount distribution on basis of the incident amount at a plurality of the incident amount prediction points; display the incident amount distribution; allow an operator to select a feature prediction point on basis of the display; and perform prediction of a feature at the selected feature prediction point.

### BRIEF DESCRIPTION OF THE DRAWINGS

FIG. 1 is a flow chart for illustrating a method for feature prediction according to an embodiment of the invention;

FIGS. 2A to 2C are schematic views for illustrating situations in major steps of the flow chart illustrated in FIG. 1;

FIGS. 3A and 3B are schematic views for illustrating a method for feature prediction according to a comparative example;

FIG. 4 is a schematic graph for illustrating the relationship between the dimension conversion difference and the space width;

FIGS. 5A and 5B are schematic views for illustrating a nonlinear pattern feature;

FIGS. 6A to 6C are schematic views for illustrating the incident angle;

FIG. 7 is a schematic graph for illustrating the effect of the height and the space width exerted on the angle θ1 perpendicular to the major surface of the wafer;

FIG. 8 is a schematic view for illustrating the angular distribution of incident objects;

FIG. 9 is a schematic view for illustrating the angular distribution of incident objects;

FIG. 10 is a schematic view for illustrating the prediction of a feature at a feature prediction point;

FIG. 11 is a schematic graph for illustrating the actual measurement values (experimental values) of the dimension conversion difference;

FIG. 12 is a schematic graph for illustrating the relationship between the function-based values and the actual measurement values (experimental values) of the dimension conversion difference;

FIG. 13 is a flow chart for illustrating a method for manufacturing a photomask according to the embodiment of the invention;

FIG. 14 is a block diagram of the method for manufacturing a photomask;

FIG. 15 is a block diagram for illustrating manufacturing and exposure of a photomask;

FIG. 16 is a flow chart for illustrating the operation sequence of a program for feature prediction according to the embodiment of the invention; and

FIGS. 17A and 17B are schematic views for illustrating the incident amount of incident objects in the cases of etching and sputtering (film formation).

### DETAILED DESCRIPTION OF THE INVENTION

Embodiments of the invention will now be illustrated with reference to the drawings. In the drawings, like components are labeled with like reference numerals, and the detailed description thereof is omitted as appropriate.

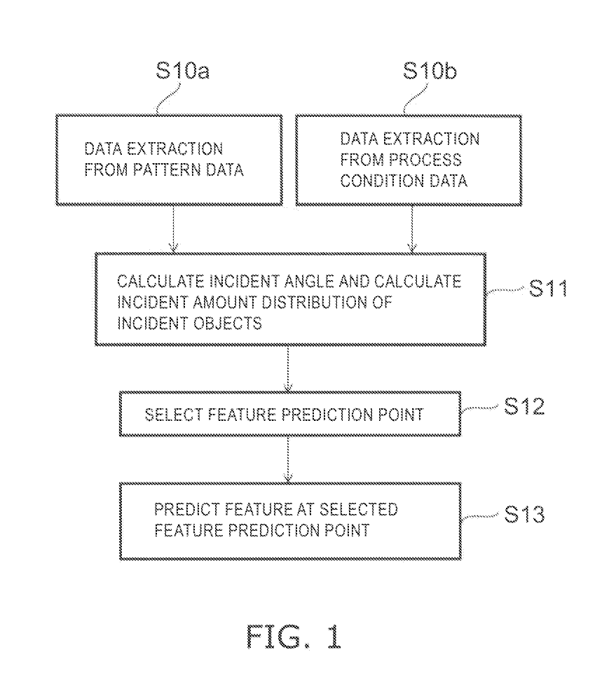

FIG. 1 is a flow chart for illustrating a method for feature prediction according to an embodiment of the invention.

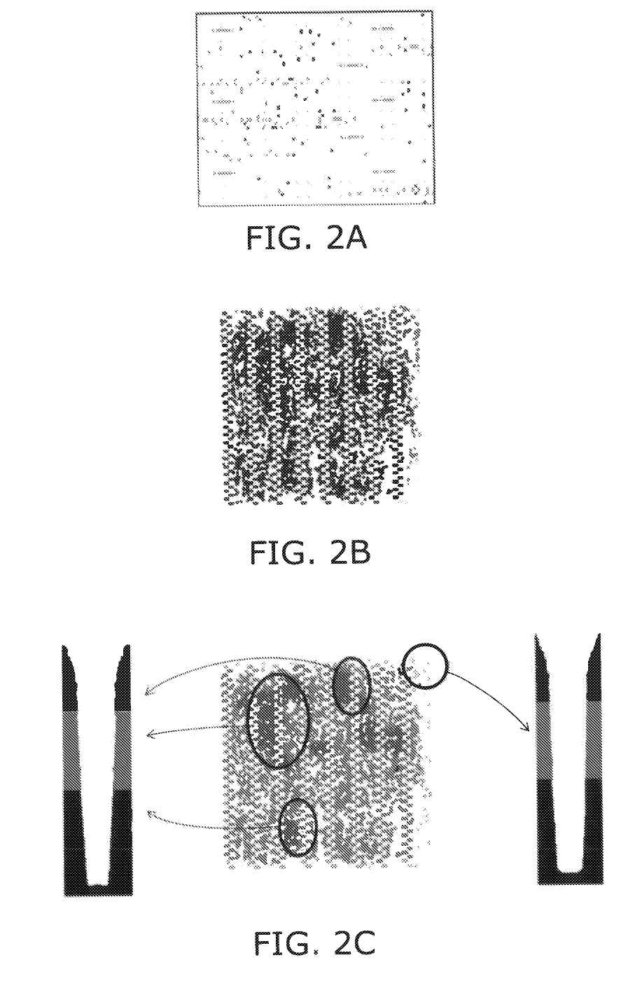

FIG. 2 is a schematic view for illustrating situations in major steps of the flow chart illustrated in FIG. 1.

In FIGS. 2B and 2C, a darker shade indicates a smaller incident amount of incident objects.

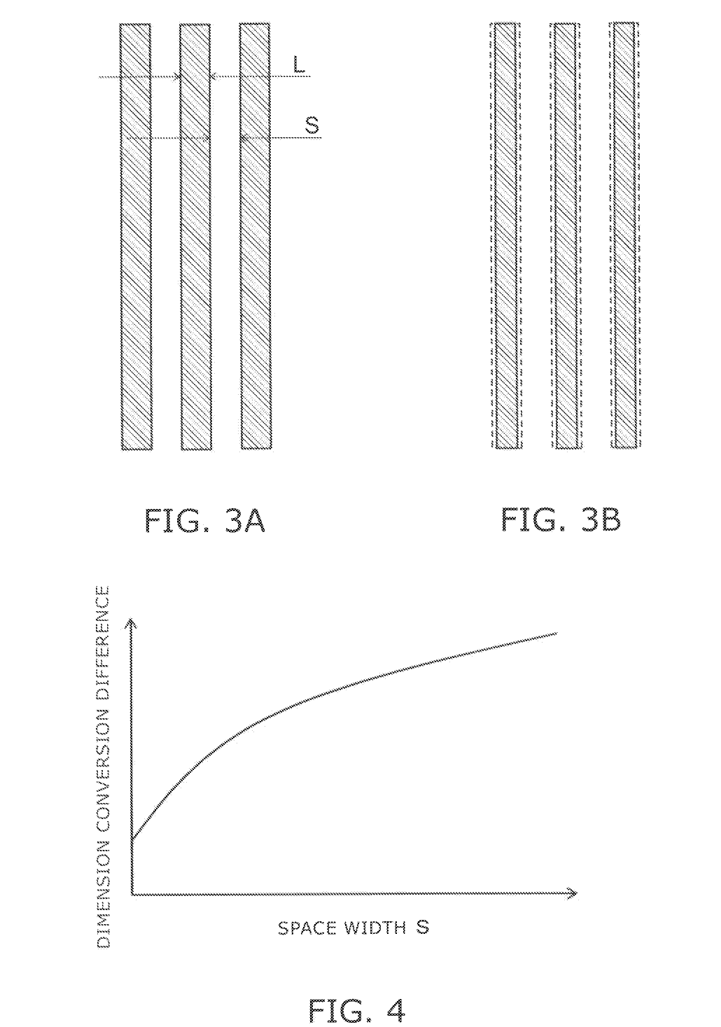

FIG. 3 is a schematic view for illustrating a method for feature prediction according to a comparative example. Here, FIG. 3A is a schematic plan view of a design pattern, and FIG. 3B is a schematic plan view of the pattern transferred onto a wafer.

First, a description is given of the method for feature prediction according to the comparative example illustrated in FIG. 3. The method for feature prediction illustrated in FIG. 3 is what was studied by the inventor in the process of reaching the invention.

If the design pattern shown in FIG. 3A is directly transferred onto a wafer, the line width L is shortened as shown in FIG. 3B. In addition, there may occur rounding of the corner, which is supposed to exhibit 90 degrees in design, and elongation of the line width L.

One of the factors causing these phenomena is what is called the process conversion difference due to the effect of etching (e.g., pattern dependence of etch rate) and the like.

In order to avoid failures due to breaks and bridges in the pattern to achieve desired electrical characteristics as a semiconductor device, dimensions just as the design pattern need to be realized on the wafer. To this end, the dimension conversion difference needs to be previously predicted (feature prediction) to correct pattern features on the photomask used in the lithography step.

Here, the dimensional accuracy of a feature to be formed is greatly affected by its layout environment of the other features placed therearound.

FIG. 4 is a schematic graph for illustrating the relationship between the dimension conversion difference and the space width S.

As shown in FIG. 4, as the space width S increases, the dimension conversion difference also increases. However, the dimension conversion difference is not necessarily proportional to the space width S. Thus, conveniently, on the basis of the line width L and space width S at a portion subjected to feature prediction (this portion being hereinafter referred to as the feature prediction point), a value of the dimension conversion difference can be selected from a set of stepwise predetermined values to perform feature prediction.

TABLE 1 illustrates values of the dimension conversion difference determined stepwise on the basis of the line width L and space width S. The values of the dimension conversion difference are previously determined by experiments and the like. Here, the line width L is 200 nm (nanometers).

TABLE 1

| SPACE WIDTH | DIMENSION CONVERSION |
|---|---|
| [nm] | DIFFERENCE [nm] |
| S < 150 | 10 |
| 150 ≦ S < 300 | 15 |
| 300 ≦ S < 600 | 20 |
| 600 ≦ S | 25 |

Thus, if the layout environment of the other surrounding features is also taken into consideration, the accuracy of feature prediction can be improved. However, actual pattern features are not limited to linear pattern features illustrated in FIG. 3. Nonlinear pattern features cause errors in feature prediction.

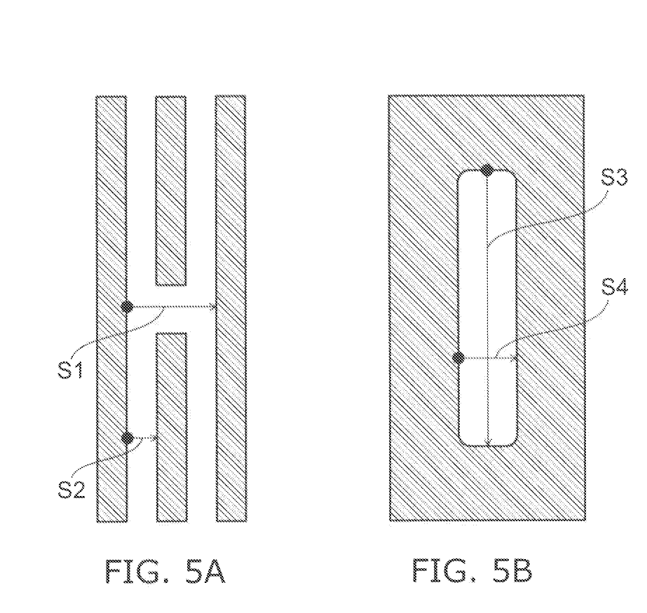

FIG. 5 is a schematic view for illustrating a nonlinear pattern feature. Here, FIG. 5A shows a discontinuous pattern feature, and FIG. 5B shows a circular pattern feature.

As shown in FIG. 5A, the space width S1 at a portion where the adjacent feature is broken is longer than the space width S2 at a portion where the adjacent feature is present. Thus, if the value of the dimension conversion difference is determined from the above TABLE 1, for example, on the basis of the space width S1, then an error occurs.

Likewise, also in the case shown in FIG. 5B, because of the difference in length between the space widths S3 and S4, the value of the dimension conversion difference determined on the basis thereof produces an error.

Furthermore, if such feature prediction is performed throughout the wafer, recent semiconductor devices with large size and high integration require time-consuming calculation because of enormous amounts of analysis data. Moreover, calculation is also performed for portions having possibly correct features where there is no need for analysis, and the analysis efficiency may decrease.

As a result of study, the inventor has found that the accuracy of feature prediction can be improved irrespective of pattern features by determining the incident angle on the basis of a pattern data (e.g., design pattern data, or interconnect pattern data after lithography simulation), determining the incident amount and its distribution from the incident angle and process condition data (e.g., the angular distribution of incident objects), and analyzing the correlation between the incident amount and the actual measurement value of the feature, thereby performing feature prediction. The inventor has also found that, if a feature prediction point is selected by providing a predetermined threshold, the calculation time can be significantly reduced, and the analysis efficiency can be significantly improved.

Next, returning to FIGS. 1 and 2, a description is given of the method for feature prediction according to the embodiment of the invention. For convenience of description, by way of example, this embodiment is described with reference to the case where a thin film formed on a wafer is etched by using a resist pattern as a mask.

As shown in FIG. 1, first, the space width S, the line width L, the height H, the layout environment of the pattern and other data are extracted from a pattern data (step S10a).

Here, the pattern data can be a design pattern data at the design time, or other pattern data such as the interconnect pattern data after lithography simulation.

Furthermore, the angular distribution of incident objects and other data are extracted from a process condition data (step S10b).

FIG. 2A is a schematic view for illustrating an example of the layout data of the pattern.

Next, an incident angle at an incident amount prediction point is calculated on the basis of the pattern data (space width S, height H, etc.), an incident amount at the incident amount prediction point is calculated on the basis of the incident angle and the process condition data, and an incident amount distribution is calculated on the basis of the incident amount at a plurality of incident amount prediction points (step S11).

FIG. 2B is a schematic view for illustrating the incident amount distribution, in which a darker shade indicates a smaller incident amount of incident objects.

Next, a feature prediction point is selected on the basis of the incident amount distribution and a predetermined threshold or manufacturing history data (step S12).

For example, a feature prediction point can be selected on the basis of the incident amount distribution and a predetermined threshold. Alternatively, if a danger site can be previously estimated from the manufacturing history data, the site can be selected as a feature prediction point.

Next, a specific feature at the selected feature prediction point is calculated to perform feature prediction (step S13).

FIG. 2C is a schematic view for illustrating the selection of a feature prediction point and the result of calculating a specific feature at the selected feature prediction point. Here, a darker shade indicates a smaller incident amount of incident objects.

For example, on the basis of a predetermined threshold, a portion with a large incident amount and a portion with a small incident amount are selected, and specific features are calculated at these portions. FIG. 2C shows the calculation result for the portion with a large incident amount on the right side of the figure, and the calculation result for the portion with a small incident amount on the left side of the figure.

Next, the content of each of the above steps is illustrated in detail.

First, the incident angle determined from the pattern data is illustrated.

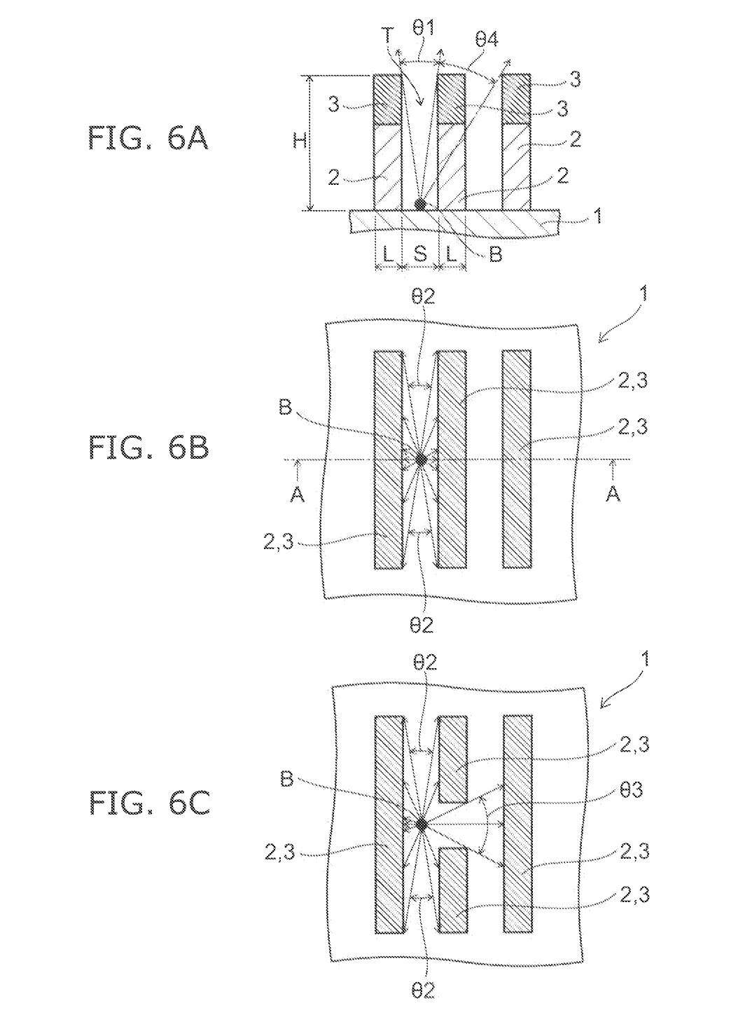

FIG. 6 is a schematic view for illustrating the incident angle, in which FIG. 6A is a schematic cross-sectional view, FIG. 6B is a schematic plan view, and FIG. 6C is a schematic plan view for illustrating a discontinuous feature. Here, FIG. 6A is a cross-sectional view taken in the direction of arrows A-A in FIG. 6B.

As shown in FIG. 6, the incident angle is calculated at an incident amount prediction point B at the bottom of a trench (groove) T. The position and the number of incident amount prediction points B can be suitably changed depending on the accuracy of the incident amount distribution to be determined.

The incident angle is defined as the angle subtended by a portion of the sphere swept by a half line radiating from the incident amount prediction point B, in which portion the half line does not interfere with the resist pattern 3 or the pattern of the insulating film 2 adjacent thereto. Thus, the incident angle is expressed by a solid angle. Such an incident angle can be determined on the basis of the pattern data.

For convenience of description, the incident angle is described more specifically with reference to a representative cross section of the “solid” formed as described above. Thus, the angle in the representative cross section is expressed by a plane angle.

For example, the angle (plane angle) perpendicular to the major surface of the wafer 1 is θ1 as shown in FIG. 6A. The angle (plane angle) parallel to the major surface of the wafer 1 is θ2 as shown in FIG. 6B.

Here, if the adjacent feature has any broken portion, the angle increases by θ3 as shown in FIG. 6C. Also in the direction perpendicular to the major surface of the wafer 1, if the adjacent feature has any broken portion, the angle increases by θ4 as shown in FIG. 6A.

The angle θ1 perpendicular to the major surface of the wafer 1 varies with the space width S and the height H of the pattern. That is, the angle θ1 increases as the space width S increases, and the angle θ1 increases as the height H decreases.

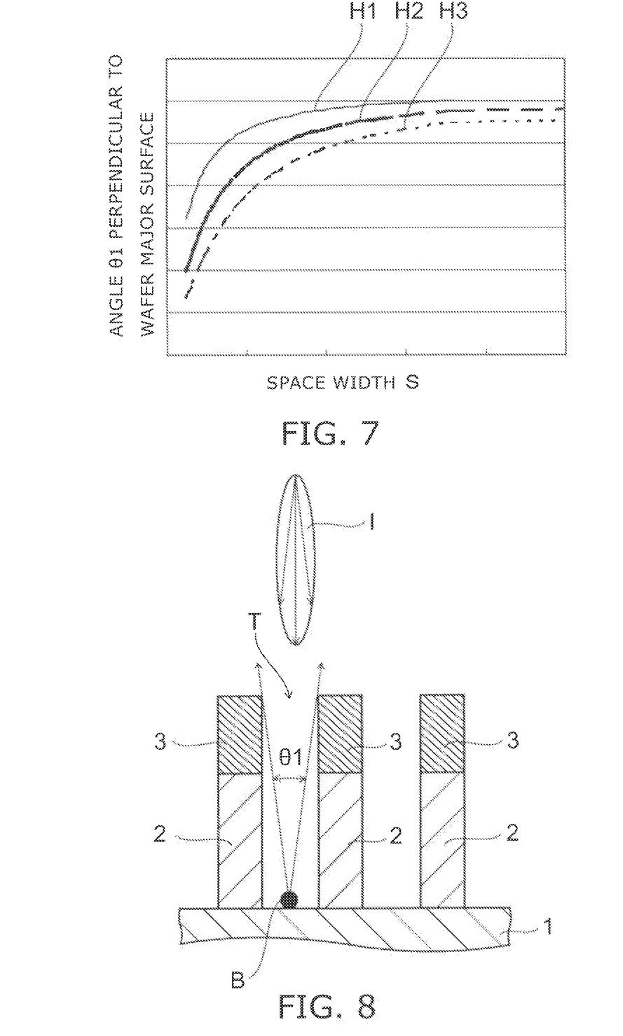

FIG. 7 is a schematic graph for illustrating the effect of the height H and the space width S exerted on the angle θ1 perpendicular to the major surface of the wafer 1. Plots H1 to H3 in the figure show the analyzed relationship between the space width S and the angle θ1 perpendicular to the major surface of the wafer 1 for each height H. Here, H1 shows the case where the height H is approximately 50 nm (nanometers), H2 shows the case where the height H is approximately 100 nm (nanometers), and H3 shows the case where the height H is approximately 150 nm (nanometers).

As shown in FIG. 7, the angle θ1 increases as the space width S increases, and even for the same space width S, the angle θ1 increases as the height H decreases.

Thus, if the relationship between the space width S and the angle θ1 perpendicular to the major surface of the wafer 1 is previously analyzed for each height H, the angle θ1 can be easily calculated using the height H as a parameter.

Next, the incident amount and the incident amount distribution are illustrated.

The incident angle affects the incident amount of incident objects (e.g., radicals and ions) at the incident amount prediction point B and contributes to feature variation (variation in the pattern dimension). That is, as the incident angle increases, the amount of incident objects capable of being incident on the incident amount prediction point B increases by the increased amount of the incident angle. This increases the amount of etching and tends to shorten the line width L.

Thus, if the incident angle is considered in feature prediction, feature prediction reflecting the layout environment in multiple directions can be effectively performed in contrast to the comparative example. Hence, the accuracy of feature prediction can be improved irrespective of pattern features.

Furthermore, in this embodiment, the angular distribution of incident objects is also considered in determining the incident amount for feature prediction. Here, the incident objects illustratively include radicals R and ions I generated from a reactive gas in a plasma state.

The space width S, line width L, height H, and layout environment can be determined from the pattern data, and the angular distribution of incident objects and the ratio of radicals R to ions I can be determined from the process condition data. That is, the incident amount of incident objects can be determined on the basis of the pattern data and the process condition data.

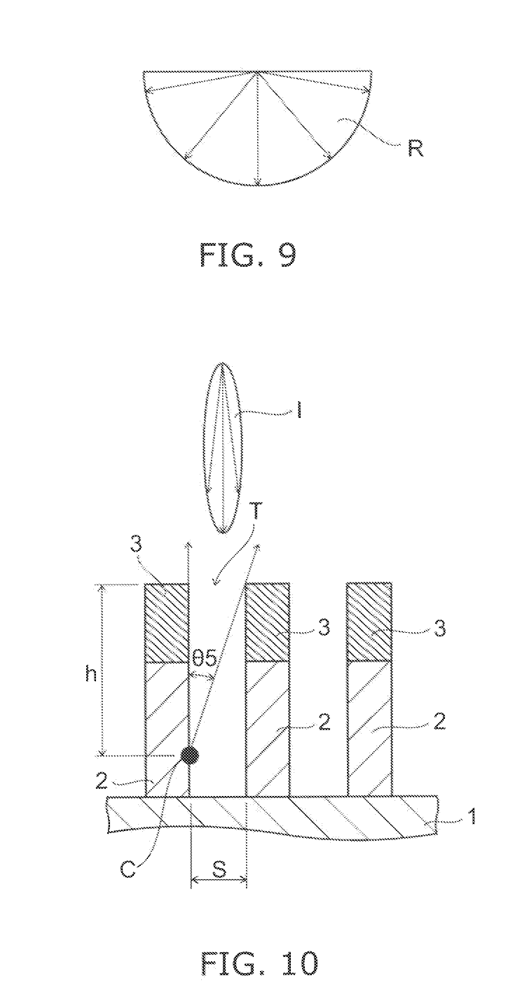

FIGS. 8 and 9 are schematic views for illustrating the angular distribution of incident objects.

As shown in FIG. 8, ions I are incident on the incident amount prediction point B with a vertically elongated angular distribution having a narrow spread. On the other hand, as shown in FIG. 9, radicals R are incident on the incident amount prediction point B with a nearly isotropic angular distribution having a wide spread.

Thus, in the upper portion of the trench T (near its opening), radicals R are more likely to be incident. On the other hand, ions I, which have a vertically elongated angular distribution with a narrow spread, can be relatively easily incident even on the bottom of the trench T. Thus, the prediction accuracy of the incident amount can be improved by considering the angular distribution of incident objects as well as the depth and aspect ratio of the trench T.

Although FIG. 8 illustrates the directly incident component directed to the incident amount prediction point B, the N-th reflection component at the sidewall of the trench T can be also taken into consideration.

In dry etching apparatuses, the ratio of radicals R to ions I used for etching depends on the type of etching. For example, radicals R primarily contribute to etching in a CDE (chemical dry etching) apparatus, whereas reactive ion etching is based on synergy between radicals R and ions I. Hence, the ratio of radicals R to ions I used for etching can be also considered in determining the incident amount of incident objects.

Furthermore, the incident amount of incident objects may also depend on the process condition of dry etching. For example, under a high processing pressure, the frequency of collisions between the ion I and the gas particle increases, and the angular distribution tends to spread. On the other hand, under a low processing pressure, the frequency of collisions between the ion I and the gas particle decreases, and the angular distribution tends to narrow. Hence, the process condition of dry etching can be also considered in determining the incident amount of incident objects.

Thus, the accuracy of the incident amount distribution can be improved by considering the incident angle and the angular distribution of incident objects in determining the incident amount of incident objects at the incident amount prediction point B.

The incident amount distribution is obtained by determining the incident amount of incident objects at a plurality of predetermined incident amount prediction points B. That is, the incident amount distribution can be determined on the basis of the incident amount at a plurality of incident amount prediction points B.

Next, selection of the feature prediction point is illustrated.

If feature prediction is performed throughout the wafer, recent semiconductor devices with large size and high integration require time-consuming calculation because of enormous amounts of analysis data. Moreover, calculation is also performed for portions having possibly correct features where there is no need for analysis, and the analysis efficiency may decrease.

Thus, in this embodiment, a feature prediction point is selected, and only the feature at the selected feature prediction point is calculated. In this case, because a specific feature is calculated only at the selected feature prediction point, the load on the calculation can be significantly reduced.

Selection of the feature prediction point can be based on the incident amount distribution determined as described above and a predetermined threshold. As described above, with the increase of the incident amount, the etching amount increases, and the line width L tends to decrease. With the decrease of the incident amount, the etching amount decreases, and the line width L tends to increase. Hence, a threshold determined from experiments and empirical rules can be used to select a danger site where occurrence of failure is anticipated from the incident amount distribution.

Furthermore, if a danger site can be previously estimated from the manufacturing history data, the site can be selected as a feature prediction point. For example, a danger site can be identified on the basis of the manufacturing history data of a previously etched wafer having a similar pattern, and a feature prediction point can be selected on the basis thereof.

A feature prediction point can be also selected by combining the selection based on a threshold with the selection based on the manufacturing history data.

Next, prediction of a feature at a feature prediction point is illustrated.

FIG. 10 is a schematic view for illustrating the prediction of a feature at a feature prediction point.

The feature of the pattern is specifically calculated at the feature prediction point selected as described above to perform feature prediction.

As shown in FIG. 10, the calculation position C of the feature is located at a dimension h downward (toward the wafer 1) from the surface of the resist pattern 3. Thus, for feature prediction, the incident angle at the calculation position C is determined similarly to the case of the incident amount prediction point B described above.

Here, because the space width S is determined at the design time, the angle θ5 perpendicular to the major surface of the wafer 1 can be treated as a function which takes the dimension h as a variable. Hence, the incident angle, which is a solid angle including the plane angle θ5, can be also treated as a function θ(h) which takes the dimension h as a variable.

Furthermore, the incident amount, which is determined from the incident angle and the angular distribution of incident objects, can be also treated as a function W(h) which takes the dimension h as a variable.

Consequently, for example, the dimension conversion difference CD, which serves as the amount of feature variation, can be expressed by a function given by the following equation (1):

Dimension conversion difference CD=α+β×incident amount W(h) (1)

where α and β are coefficients, which can be determined by the regression analysis technique described below.

The least square method can be used to determine the coefficients α, β in equation (1) by regression analysis. More specifically, the coefficients α, β can be determined so as to minimize the squared average of the difference between the actual measurement value (experimental value) and the calculated value of the dimension conversion difference. Here, it is also possible to perform the above calculation by selecting the dimension h such that the error with respect to the actual measurement value is minimized.

Although the calculation position C of the feature is located on a sidewall portion of the trench T, the calculation position C can be located on a bottom portion of the trench T to calculate the feature of the bottom portion.

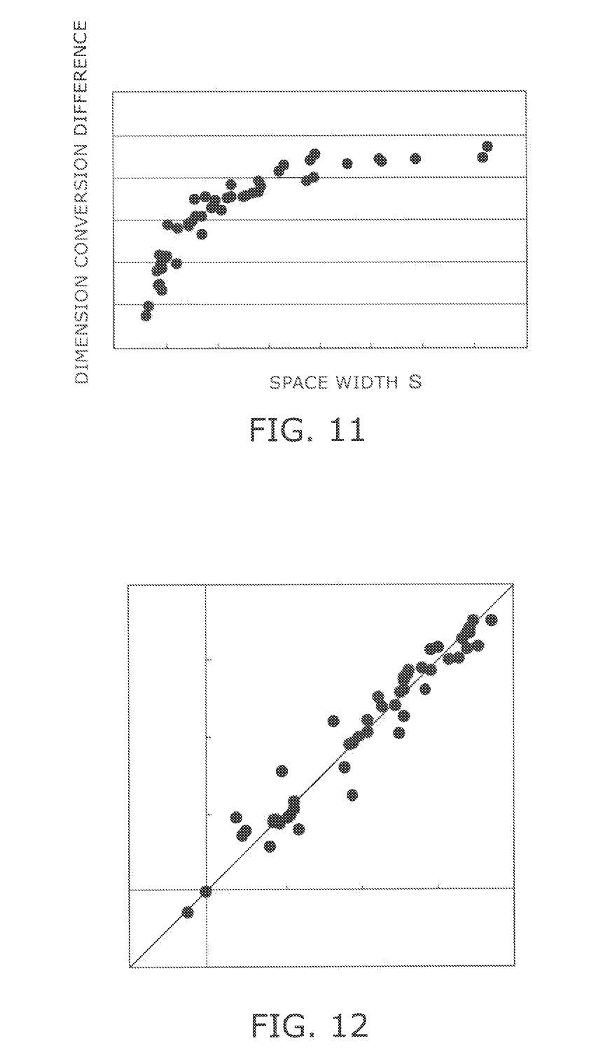

FIG. 11 is a schematic graph for illustrating the actual measurement values (experimental values) of the dimension conversion difference.

The above determination of the coefficients α, β can be facilitated by measuring the actual measurement values (experimental values) of the dimension conversion difference as shown in FIG. 11 for each of the predetermined dimensions h and compiling the values into a database.

FIG. 12 is a schematic graph for illustrating the relationship between the function-based values and the actual measurement values (experimental values) of the dimension conversion difference. In the graph, bullets represent the actual measurement values (experimental values) of the dimension conversion difference, and the straight line represents the functional expression (equation (1)) of the dimension conversion difference.

It is seen from FIG. 12 that the values of the dimension conversion difference based on the expression of the dimension conversion difference as determined by regression analysis well approximate the actual measurement values (experimental values) of the dimension conversion difference. Thus, by determining the dimension conversion difference using the expression of the dimension conversion difference to predict a feature at the feature prediction point, feature prediction with high accuracy can be performed.

The values of the coefficients α, β can be suitably determined on the basis of the actual measurement values (experimental values) of the dimension conversion difference measured under various specific conditions.

Furthermore, it is also possible to determine stepwise the value of the dimension conversion difference on the basis of the incident amount.

For example, the discrepancy of the dimension conversion difference from its actual measurement value (experimental value) can be reduced by determining stepwise the dimension conversion difference using regression analysis and the like. By predicting a feature at the feature prediction point on the basis of the value of the dimension conversion difference determined stepwise, feature prediction with high accuracy can be performed.

The analysis technique illustrated in the foregoing is the regression analysis technique, which is a kind of multivariate analysis techniques, but the invention is not limited thereto. For example, other multivariate analysis techniques or response surface techniques can be used to analyze the correlation between the incident amount and the actual measurement value (experimental value) of the dimension conversion difference to develop a compact model, and feature prediction can be performed on the basis of the model under various specific conditions.

In the foregoing, selection of a feature prediction point is based on the incident amount distribution and a predetermined threshold or manufacturing history data. However, it is also possible to allow a human operator to select a feature prediction point.

In this case, like the foregoing, the incident angle at the incident amount prediction point is determined on the basis of the pattern data, the incident amount at the incident amount prediction point is determined on the basis of the incident angle and the process condition data, and the incident amount distribution is determined on the basis of the incident amount at a plurality of incident amount prediction points. The determined incident amount distribution can be displayed on a display device to allow a human operator to select a feature prediction point on the basis of the displayed content so that a feature at the selected feature prediction point is predicted.

Thus, the experience of the human operator can be also reflected in the prediction.

As described above, according to this embodiment, the accuracy of feature prediction can be improved irrespective of pattern features. Thus, it is possible to prevent degradation in electrical characteristics due to the deformed pattern as well as bridges and breaks in the pattern, achieving improvement in quality as well as productivity.

Furthermore, danger points can be also accurately extracted, and hence the verification accuracy for the design pattern data can be also improved.

Moreover, a feature prediction point is selected, and only the feature at the selected feature prediction point is calculated. Hence, the load on the calculation can be significantly reduced, and the analysis efficiency can be also improved.

Next, a method for manufacturing a photomask according to an embodiment of the invention is illustrated.

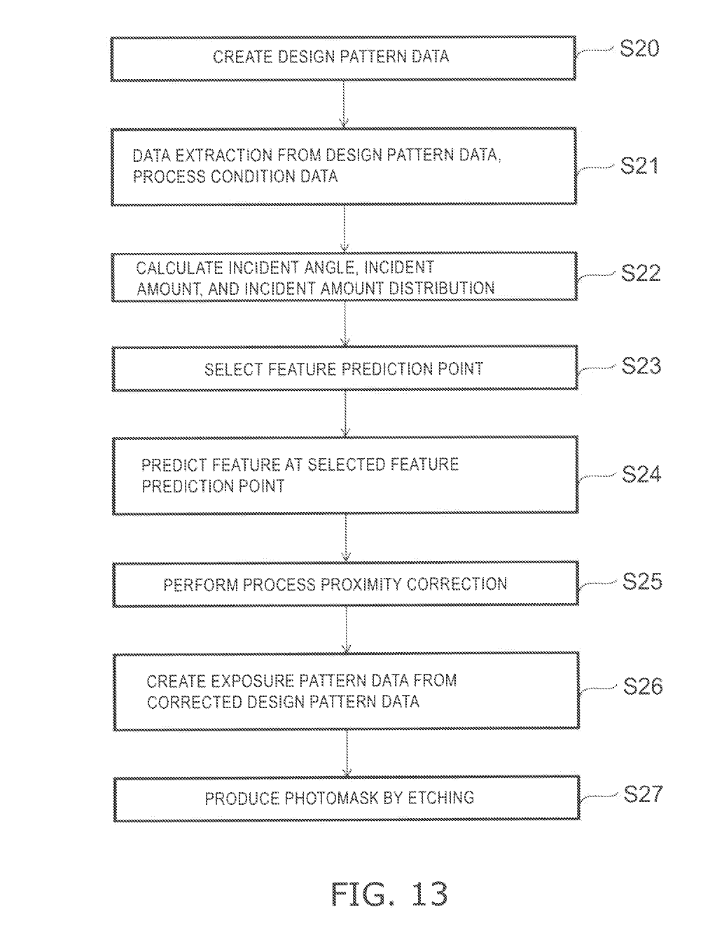

FIG. 13 is a flow chart for illustrating a method for manufacturing a photomask according to the embodiment of the invention. Steps S20 to S24 are similar to the method for feature prediction described above, and hence the description thereof is omitted as appropriate.

First, a design pattern data (the data of a pattern to be formed on a wafer) is created (step S20).

Next, the space width S, the line width L, the height H, the layout environment of the pattern and other data are extracted from the design pattern data. Furthermore, the angular distribution of incident objects and other data are extracted from the process condition data (step S21).

Next, an incident angle is calculated from the data such as the space width S and the height H, and an incident amount and its distribution is calculated from the incident angle and the data such as the angular distribution of incident objects (step S22).

Next, a feature prediction point is selected (step S23).

Here, for example, the feature prediction point can be selected on the basis of the incident amount distribution and a predetermined threshold or manufacturing history data.

Next, a specific feature at the selected feature prediction point is calculated to perform feature prediction (step S24).

Here, for example, correlation can be analyzed between the actual measurement values (experimental values) of the dimension conversion difference and the calculation expression of the dimension conversion difference parameterized by the incident amount, and a predicted value of the dimension conversion difference can be calculated on the basis of the calculation expression determined by the analysis to perform feature prediction.

Calculation of the incident angle and incident amount, analysis of correlation, and selection of a feature prediction point are the same as those described above, and hence the description thereof is omitted.

Next, process proximity correction is performed using the determined feature (value of the dimension conversion difference) (step S25).

Here, optical proximity correction can be also performed simultaneously. Conventionally known techniques are applicable to the optical proximity correction, and hence the description thereof is omitted.

If the corrected design pattern data includes any portion violating the design rule, the design pattern data is modified, and the modified data can be again subjected to process proximity correction and optical proximity correction.

Next, an exposure pattern data is created from the corrected design pattern data (step S26).

As described above, the design pattern data is corrected on the basis of the feature (dimension conversion difference) predicted by the above method for feature prediction, and the exposure pattern data is created.

Next, a photomask is produced by etching on the basis of the created exposure pattern data (step S27).

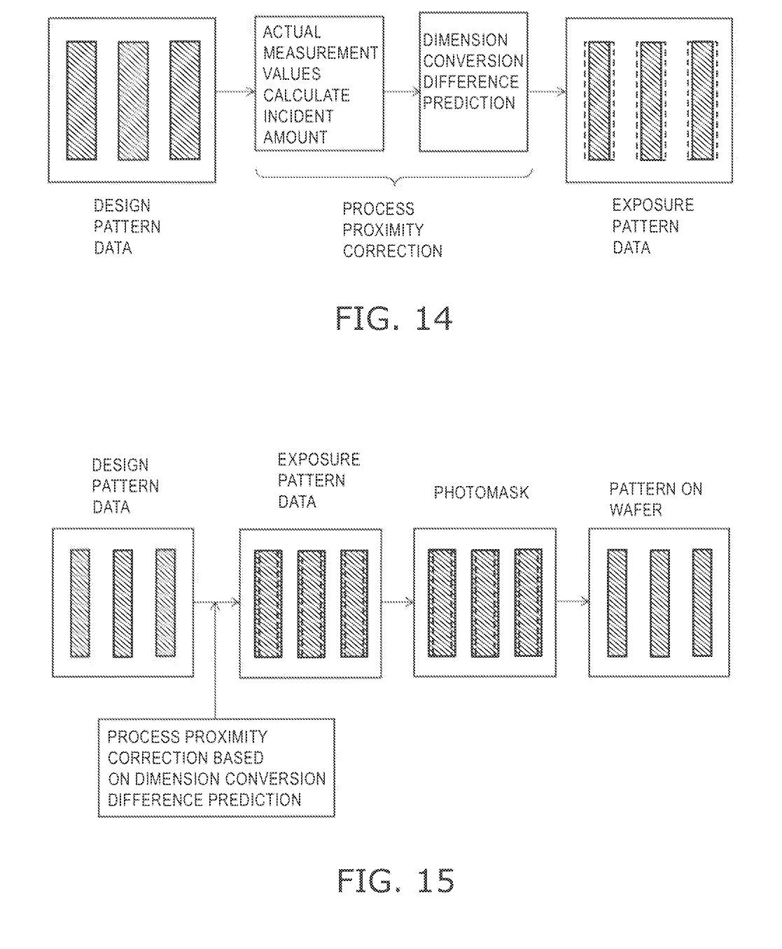

FIG. 14 is a block diagram of the method for manufacturing a photomask.

As shown in FIG. 14, an exposure pattern data is created by performing process proximity correction on the design pattern data. Here, the incident amount is calculated as described above to analyze their correlation with actual measurement values, and feature prediction (dimension conversion difference prediction) is performed on the basis thereof.

According to this embodiment, the accuracy of feature prediction can be improved irrespective of pattern features, and hence accurate correction can be performed. Thus, a photomask with small dimension conversion difference can be obtained. Furthermore, extraction of danger points and calculation of interconnect resistance and capacitance can be accurately performed, and hence a photomask with high manufacturing yield can be obtained.

Next, a method for manufacturing an electronic component according to an embodiment of the invention is described with a method for manufacturing a semiconductor device taken as an example.

The method for manufacturing a semiconductor device includes repeating the step of forming a pattern on a wafer by film formation, resist coating, exposure, development, etching, and resist removal, and the steps of inspection, cleaning, heat treatment, impurity doping, diffusion, and planarization. In such a method for manufacturing a semiconductor device, a photomask is manufactured by the above method for manufacturing a photomask, and exposure is performed using the photomask thus manufactured. Furthermore, verification of the design pattern data such as extraction of danger points is performed on the basis of the feature predicted by the above method for feature prediction.

The steps other than the method for feature prediction and the method for manufacturing a photomask described above can be based on conventionally known techniques for the respective steps, and hence the description thereof is omitted.

FIG. 15 is a block diagram for illustrating manufacturing and exposure of a photomask.

As shown in FIG. 15, process proximity correction based on feature prediction (dimension conversion difference prediction) is performed on a design pattern data, and an exposure pattern data is created from the corrected design pattern data. Here, optical proximity correction can be also performed simultaneously. Next, a photomask is produced on the basis of the exposure pattern data, and the photomask is used to perform exposure, development, etching, and resist removal to form a pattern on a wafer. Here, the accuracy can be improved in extracting danger points from the corrected design pattern data and calculating interconnect resistance and capacitance.

Next, a program for feature prediction according to an embodiment of the invention is illustrated.

The program for feature prediction according to this embodiment is intended to cause a computer to perform the method for feature prediction based on the incident amount of incident objects.

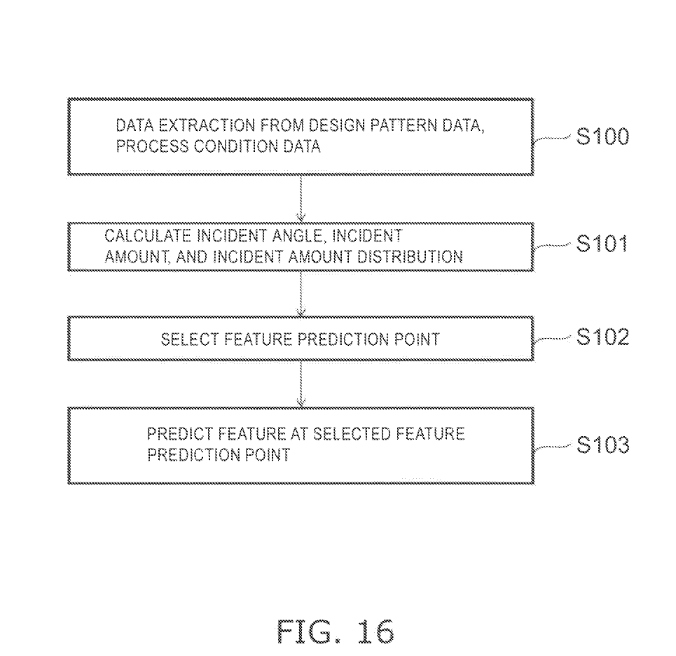

FIG. 16 is a flow chart for illustrating the operation sequence of a program for feature prediction according to an embodiment of the invention.

First, the space width S, the line width L, the height H, the layout environment of the pattern and other data are extracted from the pattern data inputted to a computer. Furthermore, the angular distribution of incident objects and other data are extracted from the process condition data (step S100).

Here, the pattern data can be a design pattern data at the design time, or other pattern data such as the interconnect pattern data after lithography simulation.

Next, an incident angle at an incident amount prediction point is calculated on the basis of the pattern data (space width S, height H, etc.), an incident amount at the incident amount prediction point is calculated on the basis of the incident angle and the process condition data, and an incident amount distribution is calculated on the basis of the incident amount at a plurality of incident amount prediction points (step S101).

Next, a feature prediction point is selected on the basis of the incident amount distribution and a predetermined threshold or manufacturing history data (step S102).

Next, a specific feature at the selected feature prediction point is calculated to perform feature prediction (step S103).

Here, for example, correlation can be analyzed between the actual measurement values (experimental values) of the dimension conversion difference inputted to the computer and the calculation expression of the dimension conversion difference parameterized by the incident amount, and a predicted value of the dimension conversion difference can be calculated on the basis of the calculation expression determined by the analysis to perform feature prediction.

Calculation of the incident angle and incident amount, analysis of correlation, and selection of a feature prediction point are the same as those described above, and hence the description thereof is omitted. Furthermore, the configuration of the computer, the input device, the display device and the like can be also based on conventionally known techniques, and hence the description thereof is omitted.

In the foregoing, selection of a feature prediction point is based on the incident amount distribution and a predetermined threshold or manufacturing history data. However, it is also possible to allow a human operator to select a feature prediction point.

In this case, like the foregoing, the incident angle at the incident amount prediction point is calculated on the basis of the pattern data, the incident amount at the incident amount prediction point is calculated on the basis of the incident angle and the process condition data, and the incident amount distribution is calculated on the basis of the incident amount at a plurality of incident amount prediction points. The incident amount distribution can be displayed on a display device to allow a human operator to select or input a feature prediction point on the basis of the displayed content, thereby causing the computer to perform prediction of a feature at the selected (inputted) feature prediction point. Thus, the experience of the human operator can be also reflected in the prediction.

For convenience of description, this embodiment has been described with reference to an example in which the method for feature prediction, the method for manufacturing a photomask, the method for manufacturing an electronic component, and the program for feature prediction according to the embodiments of the invention are used to manufacture a semiconductor device, but the invention is not limited thereto. For example, the invention is widely applicable to manufacturing of electronic components based on photolithography such as pattern formation in manufacturing liquid crystal display devices (e.g., manufacturing of color filters and array substrates).

The method for feature prediction, the method for manufacturing a photomask, the method for manufacturing an electronic component, and the program for feature prediction according to the embodiments of the invention have been described with reference to the example of pattern etching. However, the invention is not limited thereto. For example, the invention is also applicable to film formation for a wafer or an electronic component.

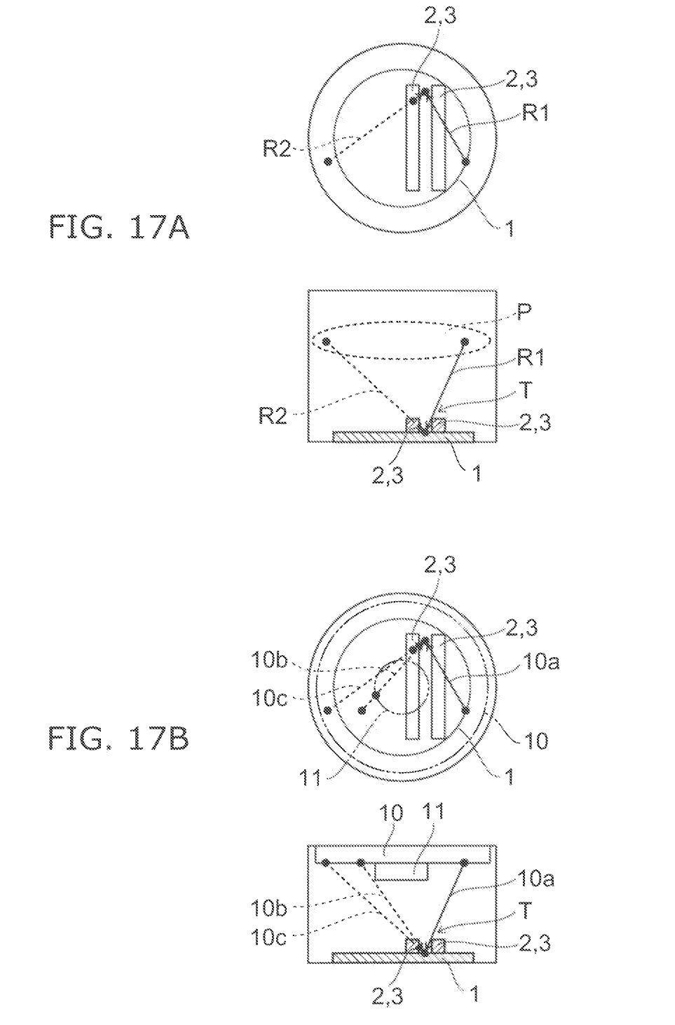

FIG. 17 is a schematic view for illustrating the incident amount of incident objects in the cases of etching and sputtering (film formation).

Here, FIG. 17A shows the case of etching, and FIG. 17B shows the case of sputtering (film formation). Each figure includes a schematic plan view on the upper side, and a schematic side view on the lower side.

In the case of etching illustrated in FIG. 17A, plasma products such as radicals and ions generated in a plasma P fly toward the surface of the wafer 1 and serve as incident objects. Here, only the plasma products R1 such as radicals and ions that do not interfere with the resist pattern 3 or the pattern of the insulating film 2 are incident into the trench T to advance etching in the trench T. On the other hand, plasma products R2 such as radicals and ions interfering with the resist pattern 3 or the pattern of the insulating film 2 cannot be incident into the trench T and do not contribute to etching in the trench T. Thus, as described above, the incident amount of incident objects contributing to etching in the trench T can be determined on the basis of the incident angle and allows feature prediction.

In the case of sputtering (film formation) illustrated in FIG. 17B, target atoms sputtered from a target 10 by positive ions in a plasma fly toward the surface of the wafer 1 and serve as incident objects. Here, film formation inside the groove advances by target atoms 10a incident into the groove on the surface of the wafer 1. On the other hand, target atoms 10b interfering with a structure 11 in the apparatus and target atoms 10c being subjected to interference on the surface of the wafer 1 and failing to be incident into the groove do not contribute to film formation inside the groove.

Thus, also in this case, the incident amount of incident objects contributing to film formation inside the groove can be determined on the basis of the incident angle and allows prediction of a feature (step coverage).

Furthermore, with regard to interference with a structure 11 in the apparatus, the process condition data includes as input the positional data of the structure in the apparatus, which is considered in calculating the incident amount.

The etching apparatus illustrated in FIG. 17A and the sputtering apparatus illustrated in FIG. 17B can be based on conventionally known techniques, and hence the description thereof is omitted.

Thus, the invention is also applicable to sputtering (film formation) to allow feature prediction.

The invention is not limited to etching in a trench T, but also applicable to etching of a contact hole, filling of a contact hole, and embedding of an interconnect.

Feature prediction can be performed on the basis of not only the design pattern data, but also other pattern data. For example, feature prediction in etching and sputtering (film formation) can be also performed on the basis of interconnect pattern data after lithography simulation.

The embodiments of the invention have been illustrated. However, the invention is not limited to the above description.

The above embodiments can be suitably modified by those skilled in the art, and such modifications are also encompassed within the scope of the invention as long as they fall within the spirit of the invention.

The elements included in the above embodiments can be combined with each other as long as feasible, and such combinations are also encompassed within the scope of the invention as long as they fall within the spirit of the invention.

1. A method for feature prediction,
determining an incident angle at an incident amount prediction point on basis of a pattern data,
determining an incident amount at the incident amount prediction point on basis of the incident angle and a process condition data,
determining an incident amount distribution on basis of the incident amount at a plurality of the incident amount prediction points,
selecting a feature prediction point on basis of the incident amount distribution and a predetermined threshold or a manufacturing history data, and
performing prediction of a feature at the selected feature prediction point.

2. The method for feature prediction according to claim 1, wherein the prediction of the feature is performed on basis of correlation between the incident amount and an actual measurement value of the feature.

3. The method for feature prediction according to claim 1, wherein the prediction of the feature is performed on basis of the correlation by a multivariate analysis technique or a response surface technique.

4. The method for feature prediction according to claim 1, wherein
an angular distribution of incident objects is determined on basis of the process condition data, and
the incident amount is determined on basis of the angular distribution of the incident objects and the incident angle.

5. The method for feature prediction according to claim 1, wherein
a ratio of radicals to ions is determined on basis of the process condition data; and
the incident amount is determined on basis of the ratio of radicals to ions and the incident angle.

6. A method for feature prediction,
determining an incident angle at an incident amount prediction point on basis of a pattern data,
determining an incident amount at the incident amount prediction point on basis of the incident angle and a process condition data,
determining an incident amount distribution on basis of the incident amount at a plurality of the incident amount prediction points,
displaying the incident amount distribution,
allowing an operator to select a feature prediction point on basis of the display, and
performing prediction of a feature at the selected feature prediction point.

7. The method for feature prediction according to claim 6, wherein the prediction of the feature is performed on basis of correlation between the incident amount and an actual measurement value of the feature.

8. The method for feature prediction according to claim 6, wherein the prediction of the feature is performed on basis of the correlation by a multivariate analysis technique or a response surface technique.

9. The method for feature prediction according to claim 6, wherein
an angular distribution of incident objects is determined on basis of the process condition data, and
the incident amount is determined on basis of the angular distribution of the incident objects and the incident angle.

10. The method for feature prediction according to claim 6, wherein
a ratio of radicals to ions is determined on basis of the process condition data, and
the incident amount is determined on basis of the ratio of radicals to ions and the incident angle.

11. A method for manufacturing a photomask,
performing process proximity correction on a design pattern data on basis of a feature predicted by the method for feature prediction,
determining an incident angle at an incident amount prediction point on basis of a pattern data,
determining an incident amount at the incident amount prediction point on basis of the incident angle and a process condition data,
determining an incident amount distribution on basis of the incident amount at a plurality of the incident amount prediction points,
selecting a feature prediction point on basis of the incident amount distribution and a predetermined threshold or a manufacturing history data, and
performing prediction of a feature at the selected feature prediction point, and
creating an exposure pattern data.

12. The method for manufacturing a photomask according to claim 11, further performing optical proximity correction.

13. A method for manufacturing a photomask,
performing process proximity correction on a design pattern data on basis of a feature predicted by the method for feature prediction,
determining an incident angle at an incident amount prediction point on basis of a pattern data,
determining an incident amount at the incident amount prediction point on basis of the incident angle and a process condition data,
determining an incident amount distribution on basis of the incident amount at a plurality of the incident amount prediction points,
displaying the incident amount distribution;
allowing an operator to select a feature prediction point on basis of the display, and
performing prediction of a feature at the selected feature prediction point, and
creating an exposure pattern data.

14. The method for manufacturing a photomask according to claim 13, further performing optical proximity correction.

15. A method for manufacturing an electronic component,
producing a photomask by the method for manufacturing a photomask,
performing process proximity correction on a design pattern data on basis of a feature predicted by the method for feature prediction,
determining an incident angle at an incident amount prediction point on basis of a pattern data,
determining an incident amount at the incident amount prediction point on basis of the incident angle and a process condition data,
determining an incident amount distribution on basis of the incident amount at a plurality of the incident amount prediction points,
selecting a feature prediction point on basis of the incident amount distribution and a predetermined threshold or a manufacturing history data, and
performing prediction of a feature at the selected feature prediction point, and
creating an exposure pattern data, and
performing exposure using the photomask.

16. A method for manufacturing an electronic component,
producing a photomask by the method for manufacturing a photomask,
performing process proximity correction on a design pattern data on basis of a feature predicted by the method for feature prediction,
determining an incident angle at an incident amount prediction point on basis of a pattern data,
determining an incident amount at the incident amount prediction point on basis of the incident angle and a process condition data,
determining an incident amount distribution on basis of the incident amount at a plurality of the incident amount prediction points,
displaying the incident amount distribution,
allowing an operator to select a feature prediction point on basis of the display, and
performing prediction of a feature at the selected feature prediction point, and
creating an exposure pattern data, and
performing exposure using the photomask.

17. A method for manufacturing an electronic component,
verifying a pattern data on basis of a feature predicted by the method for feature prediction,
determining an incident angle at an incident amount prediction point on basis of a pattern data,
determining an incident amount at the incident amount prediction point on basis of the incident angle and a process condition data,
determining an incident amount distribution on basis of the incident amount at a plurality of the incident amount prediction points,
selecting a feature prediction point on basis of the incident amount distribution and a predetermined threshold or a manufacturing history data, and
performing prediction of a feature at the selected feature prediction point.

18. A method for manufacturing an electronic component,
verifying a pattern data on basis of a feature predicted by the method for feature prediction,
determining an incident angle at an incident amount prediction point on basis of a pattern data,
determining an incident amount at the incident amount prediction point on basis of the incident angle and a process condition data,
determining an incident amount distribution on basis of the incident amount at a plurality of the incident amount prediction points,
displaying the incident amount distribution;
allowing an operator to select a feature prediction point on basis of the display, and
performing prediction of a feature at the selected feature prediction point.

19. A program for feature prediction causing a computer to:
calculate an incident angle at an incident amount prediction point on basis of a pattern data;
calculate an incident amount at the incident amount prediction point on basis of the incident angle and a process condition data;
calculate an incident amount distribution on basis of the incident amount at a plurality of the incident amount prediction points;
select a feature prediction point on basis of the incident amount distribution and a predetermined threshold or a manufacturing history data and perform prediction of a feature at the selected feature prediction point.

20. A program for feature prediction causing a computer to:
calculate an incident angle at an incident amount prediction point on basis of a pattern data;
calculate an incident amount at the incident amount prediction point on basis of the incident angle and a process condition data;
calculate an incident amount distribution on basis of the incident amount at a plurality of the incident amount prediction points;
display the incident amount distribution;
allow an operator to select a feature prediction point on basis of the display; and
perform prediction of a feature at the selected feature prediction point.
